(19) United States
(12) Patent Application Publication
(10) Pub. No.: US 2005/0019673 A1
(43) Pub. Date: Jan. 27, 2005

(54) Attenuated film with etched quartz phase shift mask

(76) Inventors: Kunal Taravade, Portland, OR (US); Ebo Croffie, Portland, OR (US); Neal Callan, Lake Oswego, OR (US)

Correspondence Address: LSI LOGIC CORPORATION, 1621 BARBER LANE, MS: D-106, MILPITAS, CA, 95035, US

(21) Appl. No.: 10/624,662

(22) Filed: Jul. 22, 2003

(51) Int. Cl. G03F 9/00

(52) U.S. Cl. 430/5

(57) ABSTRACT

A phase shift mask which includes an etched quartz region that provides a 180 degree phase shift, and an attenuated film which provides a 0 (or 360) degree phase shift. The phase shift mask provides performance comparable to CPL, while at the same time, avoiding the problems and manufacturability issues associated with EDA. The phase shift mask has better contrast than CPL, and a process window that is comparable to both CPL and alternating phase shift masks. The phase shift mask that does not require a second critical write, as is the case with CPL, does not need a second mask to eliminate unwanted patterns resulting from phase edges, and does not need a complicated EDA solution (like CPL). Finally, the phase shift mask is simple to manufacture, requiring only a single write step if employed with the back-side exposure technique which is well known in the mask-making industry.

### BACKGROUND

The present invention generally relates to photolithography, and more specifically relates to phase shift masks.

Microlithography is used to manufacture integrated circuits, magnetic devices, and other microdevices. In microlithography, a final product is manufactured in a multiple step process, where initially a “resist” material is produced with each pattern subsequently defining a product attribute. “Resists” are generally formed of polymer compositions, and are sensitive to light or other forms of radiation. The patterns are formed in the resist by exposing different regions of the resist material to different radiation doses. In bright regions, chemical changes occur in the resist that cause it to dissolve more easily (for positive resist) or less easily (for negative resists) than in dim regions. The bright and dim regions are exposed using an exposure tool which generally transfers corresponding features from a mask or reticle. The masks or reticles are generally plates of quartz coated with an opaque material such as chrome. The chrome is etched away to form the mask. The radiation used may be, for example, ultraviolet light and x-rays, and the regions of the mask that are opaque and transparent form a pattern of bright and dark when illuminated uniformly.

Typically, a projection lens is used to form an image of the mask pattern on the resist film. The patterns formed in the resist are not identical to those on the mask, and the methods of obtaining the pattern desired for the ultimate manufactured device in spite of deficiencies in the process is called “wavefront engineering.” This includes Optical and Process Correction or Optical Proximity Correction (OPC), wherein edge placements are manipulated, and off-axis illuminations. Among the various devices used are phase shift masks (PSMs), which create desired dark regions through interference. Phase shift masks and their use in photolithography are described in detail in several existing documents, including U.S. Pat. Nos. 5,620,816; 5,807,649; 6,251,549; 6,287,732 and 6,479,196, all of which are incorporated herein by reference in their entirety.

FIG. 1 depicts standard mask processing steps. First, as shown in image A in FIG. 1, a blank mask/resist 10 is coated onto a substrate of chrome 12 and quartz 14. Then, as shown in image B in FIG. 1, the pattern is written and developed. Next, as shown in image C in FIG. 1, the chrome 12 is etched. Finally, as shown in image D in FIG. 1, the resist 10 is stripped and cleaned, leaving a substrate of quartz 14 with a chrome pattern 12 thereon.

In order to pattern progressively smaller circuit features, while still maintaining a cost-effective manufacturing strategy, strong (or alternating) phase shift masks have been used, as well as chromeless phase lithography (CPL). Alternating phase shift masks require 0 and 180 degree alternating regions around chrome features. This eliminates the zeroeth order of the diffracted light, while simultaneously doubling the effective pitch. Both result in a larger process window. Alternating phase shift masks are not very cost effective as an ASIC solution, as they require the use of a second mask to “trim” out unwanted dark lines caused by the phase transition between 0 and 180 degree edges.

With regard to CPL, CPL requires extremely small quartz mesas, which define the lines printed on the wafer. Combined with an off-axis illumination scheme, this also increases the process window for small features and extends conventional 248 nm lithography. CPL requires “chrome islands” in addition to chromeless features in order to print large areas. Additionally, EDA software is required to deconvolve an arbitrary design into the various layers which will comprise the CPL layout, and this is not trivial to implement. Furthermore, the large chromeless regions pose significant problems during inspection, and the need to have critical chrome islands interspersed among critical quartz trenches requires two critical writes, increasing the cost of manufacturing.

### OBJECTS AND SUMMARY

An object of an embodiment of the present invention is to provide a phase shift mask that provides performance comparable to CPL, while at the same time, avoiding the problems of EDA and the manufacturability issues associated with EDA.

Another object of an embodiment of the present invention is to provide a phase shift mask that has better contrast than CPL, and a process window that is comparable to both CPL and alternating phase shift masks.

Still another object of an embodiment of the present invention is to provide a phase shift mask that does not require a second critical write, as is the case with CPL, does not need a second mask to eliminate unwanted patterns resulting from phase edges, and does not need a complicated EDA solution (like CPL).

Still yet another object of an embodiment of the present invention is to provide a phase shift mask that is simple to manufacture, requiring only a single write step if employed with the back-side exposure technique which is well known in the mask-making industry.

Briefly, and in accordance with at least one of the foregoing objects, an embodiment of the present invention provides a phase shift mask which includes an etched quartz region that provides a 180 degree phase shift, and an attenuated film which provides a 0 (or 360) degree phase shift. Another embodiment of the present invention provides a method of making such a phase shift mask.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein:

FIG. 1 provides a series of images (not to scale) which illustrate the steps which are performed during standard mask processing;

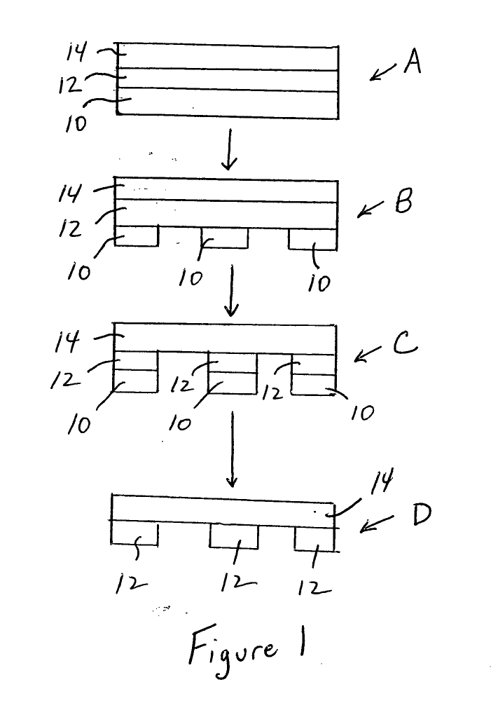

FIG. 2 provides a block diagram of a method of manufacturing a phase shift mask, where the method is in accordance with an embodiment of the present invention; and

FIG. 3 provides a series of images (not to scale) which illustrate a phase shift mask as it is being manufactured using the method shown in FIG. 2.

### DESCRIPTION

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

An embodiment of the present invention provides a phase shift mask that provides performance comparable to CPL, while at the same time, avoiding the problems of EDA and the manufacturability issues associated with EDA. The phase shift mask has better contrast than CPL, and a process window that is comparable to both CPL and alternating phase shift masks. The phase shift mask that does not require a second critical write, as is the case with CPL, does not need a second mask to eliminate unwanted patterns resulting from phase edges, and does not need a complicated EDA solution (like CPL). Finally, the phase shift mask is simple to manufacture, requiring only a single write step if employed with the back-side exposure technique which is well known in the mask-making industry.

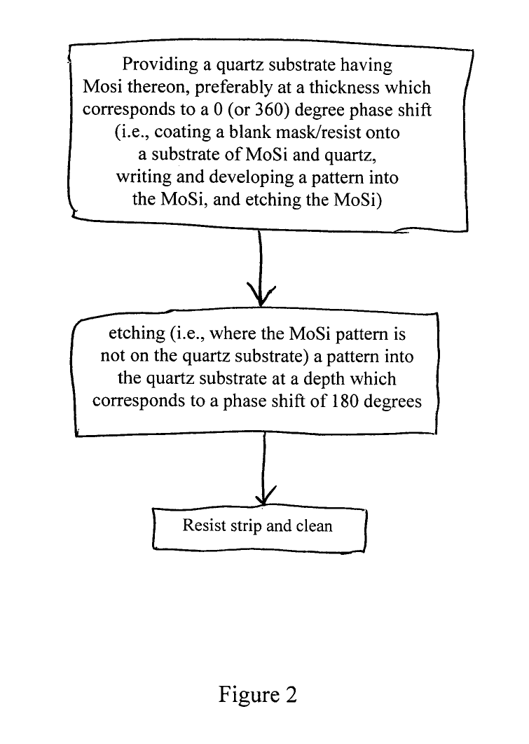

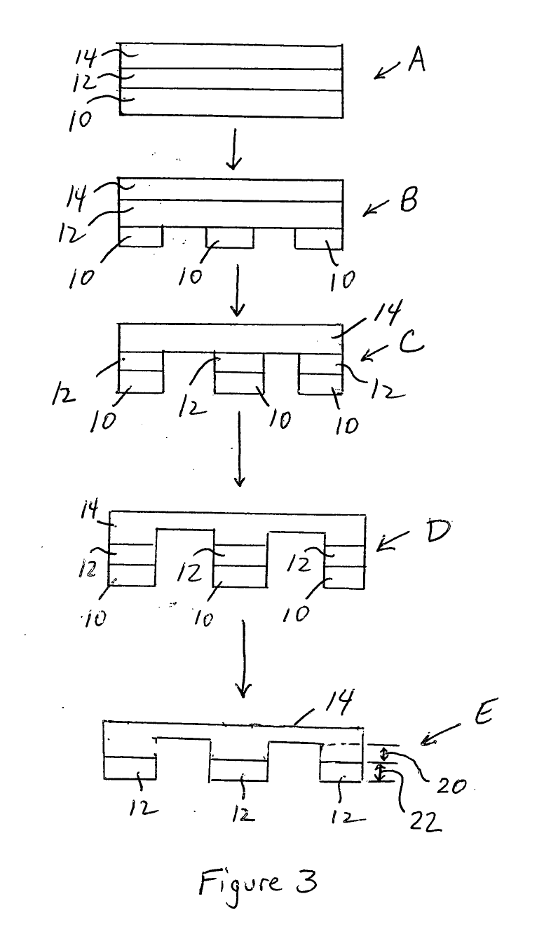

FIG. 2 provides a block diagram of a method of manufacturing the phase shift mask, and FIG. 3 provides a series of images (not to scale) which illustrate a phase shift mask as it is being manufactured using the method shown in FIG. 2.

First, as shown in FIG. 2 and in image A in FIG. 3, a blank mask/resist 10 is coated onto a substrate of MoSi 12 and quartz 14. Then, as shown in FIG. 2 and in image B in FIG. 3, the pattern is written and developed. Next, as shown in FIG. 2 and in image C in FIG. 3, the MoSi 12 is etched. Subsequently, as shown in FIG. 2 and in image D in FIG. 3, after the MoSi 12 is etched, the quartz 14 is etched. Preferably, as shown in FIG. 2 and in image E in FIG. 3, the quartz 14 is etched to a depth (dimension 20) that corresponds to a phase shift of 180 degrees. Additionally, preferably the MoSi is provided at a thickness (dimension 22) which corresponds to 0 (or 360) degree phase shift. As shown in FIG. 2 and in image E in FIG. 3, after the MoSi 12 is etched and the quartz 14 is etched, the resist 10 is stripped and cleaned.

While an embodiment of the present invention is shown and described, it is envisioned that those skilled in the art may devise various modifications of the present invention without departing from the spirit and scope of the appended claims.

1. A phase shift mask comprising: a quartz substrate which includes an etch depth that corresponds to a 180 phase shift; and a pattern on the quartz substrate, wherein the pattern has a thickness which corresponds to at least one of a 0 and 360 degree phase shift.

2. A phase shift mask as recited in claim 1, wherein the pattern comprises attenuated film.

3. A phase shift mask as recited in claim 1, wherein the pattern comprises MoSi.

4. A method of manufacturing a phase shift mask, said method comprising: providing a quartz substrate having a pattern thereon having a thickness which corresponds to at least one of a 0 and 360 degree phase shift; and etching the quartz substrate to a depth that corresponds to a 180 phase shift.

5. A method as recited in claim 4, wherein the step of etching the quartz substrate comprises etching a pattern into the quartz substrate.

6. A method as recited in claim 4, wherein the step of etching the quartz substrate comprises etching where the pattern is not on the quartz substrate.

7. A method as recited in claim 4, wherein the step of providing a quartz substrate having a pattern thereon comprises coating a blank mask/resist onto a substrate of MoSi and quartz, writing and developing a pattern into the MoSi, and etching the MoSi.
